(19) United States
(12) Patent Application Publication
(10) Pub. No.: US 2026/0190879 A1
(43) Pub. Date: Jul. 2, 2026

(54) SYSTEMS, METHODS, AND COMPUTER PROGRAM PRODUCTS FOR FORMING SEMICONDUCTOR STRUCTURES ON SUBSTRATES

(71) Applicant: ASM IP Holding B.V., Almere (NL)

(72) Inventors: Cheng-Wei Chang, Chandler, AZ (US); Young Pil Kim, Scottsdale, AZ (US); Bubesh Babu Jotheeswaran, Gilbert, AZ (US); Caleb Miskin, Mesa, AZ (US)

(21) Appl. No.: 19/435,013

(22) Filed: Dec. 29, 2025

Related U.S. Application Data
(60) Provisional application No. 63/740,528, filed on Dec. 31, 2024.

(51) Int. Cl. H10P 14/20; C23C 16/30; C23C 16/52; H10D 62/832; H10D 62/834; H10P 14/24

(52) U.S. Cl. CPC H10P 14/3444; C23C 16/30; C23C 16/52; H10D 62/832; H10D 62/834; H10P 14/24; H10P 14/3411

(57) ABSTRACT

A semiconductor processing system includes a chamber arrangement and a processor. The processor is operatively connected to the chamber arrangement and is responsive to instructions recorded on a non-transitory machine-readable medium to seat a substrate in the chamber arrangement, deposit a first boron-doped silicon germanium layer on the substrate, deposit a second boron-doped silicon germanium layer onto the first boron-doped silicon germanium layer, and deposit a boron-doped silicon layer onto the second boron-doped silicon germanium layer. The first boron-doped silicon germanium layer is deposited at a first boron-doped silicon germanium layer deposition pressure, the second boron-doped silicon germanium layer is deposited at a second boron-doped silicon germanium layer deposition pressure, and the first boron-doped silicon germanium layer deposition pressure is greater than the second boron-doped silicon germanium layer deposition pressure. Methods of forming semiconductor structures, semiconductor structures, and computer program products are also described.

### CROSS-REFERENCE TO RELATED APPLICATIONS

This application is a nonprovisional of, and claims priority to and the benefit of, U.S. Provisional Ser. No. 63/740,528 , filed Dec. 31, 2024 and entitled “SYSTEMS, METHODS, AND COMPUTER PROGRAM PRODUCTS FOR FORMING SEMICONDUCTOR STRUCTURES ON SUBSTRATES,” which is hereby incorporated by reference herein.

### FIELD OF INVENTION

The present disclosure generally relates to depositing layers on substrates, and more particularly, to depositing semiconductor structures on substrates.

### BACKGROUND OF THE DISCLOSURE

Films are commonly deposited onto substrates, such as during the fabrication of semiconductor devices. Deposition is generally accomplished by heating the substrate to a desired deposition temperature in a reactor and contacting the substrate with one or more film precursors under conditions selected to cause the film to deposit on the substrate such as pressure and/or flow conditions. Once the material develops a desired property, such as thickness and/or electrical resistivity, the substrate is typically sent on for further processing, as appropriate for the device being formed using the film. In some film deposition processes the substrate may have exposed surfaces having differing compositions, such as different chemical and/or crystalline structure, potentially causing the film to deposit at different rates and/or with different properties according to influence of the differing exposed surfaces. In such deposition processes it may be necessary to tune the deposition process to cause the film to have the properties desired for the device being fabricated. While generally satisfactory for its intended purposes, the tuning typically prolongs the deposition process, limiting throughput of the reactor used to deposit the film on the substrate.

Such methods and systems have generally been considered suitable for their intended purpose. However, there remains a need in the art for semiconductor processing systems, methods of making semiconductor structures, and related semiconductor structures and computer program products. The present disclosure provides a solution to this need.

### SUMMARY OF THE DISCLOSURE

A semiconductor processing system is provided. The semiconductor processing system includes a chamber arrangement and a processor. The processor is operatively connected to the chamber arrangement and is responsive to instructions recorded on a non-transitory machine-readable medium to seat a substrate in the chamber arrangement, deposit a first boron-doped silicon germanium layer on the substrate, deposit a second boron-doped silicon germanium layer onto the first boron-doped silicon germanium layer, and deposit a boron-doped silicon layer onto the second boron-doped silicon germanium layer. The first boron-doped silicon germanium layer is deposited at a first boron-doped silicon germanium layer deposition pressure, the second boron-doped silicon germanium layer is deposited at a second boron-doped silicon germanium layer deposition pressure, and the first boron-doped silicon germanium layer deposition pressure is greater than the second boron-doped silicon germanium layer deposition pressure.

In addition to one or more of the features described above, or as an alternative, further examples of the system may include that the first boron-doped silicon germanium layer deposition pressure is between about 10 Torr and about 300 Torr, or between about 10 Torr and about 200 Torr, or between about 10 Torr and about 100 Torr, or between about 50 Torr and 100 Torr; and wherein the second boron-doped silicon germanium layer deposition pressure is between about 10 Torr and about 100 Torr, or between about 10 Torr and about 80 Torr, or between about 10 Torr and about 60 Torr, or between about 25 Torr and about 40 Torr.

In addition to one or more of the features described above, or as an alternative, further examples of the system may include that a ratio of the first boron-doped silicon germanium layer deposition pressure to the second boron-doped silicon germanium layer deposition pressure is between about 2:1 and about 10:1, or between about 2:1 and about 8:1, or between about 2:1 and 6:1, or between about 2:1 and about 4:1.

In addition to one or more of the features described above, or as an alternative, further examples of the system may include the instructions further cause the processor to deposit the boron-doped silicon layer at a boron-doped silicon layer deposition pressure, and wherein the boron-doped silicon layer deposition pressure is greater than the second boron-doped silicon germanium layer deposition pressure.

In addition to one or more of the features described above, or as an alternative, further examples of the system may include that the boron-doped silicon layer deposition pressure is less than the first boron-doped silicon germanium layer deposition pressure. The boron-doped silicon layer deposition pressure is between about 10 Torr and about 100 Torr, or between about 10 Torr and about 80 Torr, or between about 10 Torr and about 60 Torr, or between about 10 Torr and about 40 Torr. A ratio of the boron-doped silicon layer deposition pressure to the second boron-doped silicon germanium layer deposition pressure is between about 1.1:1 and about 5:1, or between about 1.1:1 and about 4:1, or between about 1.1:1 and about 3:1, or between about 1.1:1 and about 2:1.

In addition to one or more of the features described above, or as an alternative, further examples of the system may include that the instructions further cause the processor to maintain the substrate at a temperature between about 500 degrees Celsius and about 1000 degrees Celsius, or between about 500 degrees Celsius and about 900 degrees Celsius, or between about 500 degrees Celsius and about 700 degrees Celsius, or between about 600 degrees Celsius and about 700 degrees Celsius continuously during deposition of each of the first boron-doped silicon germanium layer, the second boron-doped silicon germanium layer, and the boron-doped silicon layer.

In addition to one or more of the features described above, or as an alternative, further examples of the system may include a precursor source coupled to the chamber arrangement and operatively associated with the processor. The instructions may further cause the processor to continuously flow a silicon-containing precursor, a germanium-containing precursor, and an etchant into the chamber arrangement from the precursor source during deposition of the first boron-doped silicon germanium layer, the second boron-doped silicon germanium layer, and the boron-doped silicon layer.

In addition to one or more of the features described above, or as an alternative, further examples of the system may include a precursor source coupled to the chamber arrangement and operatively associated with the processor. The instructions may further cause the processor to continuously flow a boron-containing precursor into the chamber arrangement from the precursor source during deposition of the first boron-doped silicon germanium layer, the second boron-doped silicon germanium layer, cease flow of the boron-containing precursor from the precursor source and into the chamber arrangement, and thereafter resume flow of the boron-containing precursor from the precursor source and into the chamber arrangement.

A method of forming a semiconductor structure is provided. The method includes seating a substrate in a chamber arrangement, depositing a first boron-doped silicon germanium layer on the substrate, depositing a second boron-doped silicon germanium layer onto the first boron-doped silicon germanium layer, and depositing a boron-doped silicon layer onto the second boron-doped silicon germanium layer. The first boron-doped silicon germanium layer is deposited at a first boron-doped silicon germanium layer deposition pressure, the second boron-doped silicon germanium layer is deposited at a second boron-doped silicon germanium layer deposition pressure, and the first boron-doped silicon germanium layer deposition pressure is greater than the second boron-doped silicon germanium layer deposition pressure to limit time required to form the semiconductor structure.

In addition to one or more of the features described above, or as an alternative, further examples of the method may include that the first boron-doped silicon germanium layer deposition pressure is between about 10 Torr and about 300 Torr, or between about 10 Torr and about 200 Torr, or between about 10 Torr and about 100 Torr, or between about 50 Torr and about 100 Torr. The second boron-doped silicon germanium layer deposition pressure is between about 10 Torr and about 100 Torr, or between about 10 Torr and about 80 Torr, or between about 10 Torr and about 60 Torr, or between about 25 Torr and about 40 Torr. A ratio of the first boron-doped silicon germanium layer deposition pressure to the second boron-doped silicon germanium layer deposition pressure is between about 1.1:1 and about 5:1, or between about 1.1:1 and about 4:1, or between about 1.1:1 and about 3:1, or between about 1.1:1 and about 2:1.

In addition to one or more of the features described above, or as an alternative, further examples of the method may include that the boron-doped silicon layer is deposited at a boron-doped silicon layer deposition pressure. The boron-doped silicon layer deposition pressure may be greater than the second boron-doped silicon germanium layer deposition pressure. The boron-doped silicon layer deposition pressure is less than the first boron-doped silicon germanium layer deposition pressure.

In addition to one or more of the features described above, or as an alternative, further examples of the method may include that a ratio of the first boron-doped silicon germanium layer deposition pressure to the second boron-doped silicon germanium layer deposition pressure is between about 2:1 and about 10:1, or between about 2:1 and about 8:1, or between about 2:1 and about 3:1, or between about 2:1 and about 4:1.

In addition to one or more of the features described above, or as an alternative, further examples of the method may include that the boron-doped silicon layer deposition pressure is between about 10 Torr and about 100 Torr, or between about 10 Torr and about 80 Torr, or between about 10 Torr and about 60 Torr, or between about 25 Torr and about 40 Torr.

In addition to one or more of the features described above, or as an alternative, further examples of the method may include continuously heating the substrate to between about 500 degrees Celsius and about 1000 degrees Celsius, or between about 500 degrees Celsius and about 900 degrees Celsius, or between about 500 degrees Celsius and about 700 degrees Celsius, or between about 600 degrees Celsius and about 700 degrees Celsius during deposition of the first boron-doped silicon germanium layer, the second boron-doped silicon germanium layer, and the boron-doped silicon layer.

In addition to one or more of the features described above, or as an alternative, further examples of the method may include continuously flowing a germanium-containing precursor into the chamber arrangement during deposition of the first boron-doped silicon germanium layer, the second boron-doped silicon germanium layer, and the boron-doped silicon layer.

In addition to one or more of the features described above, or as an alternative, further examples of the method may include continuously flowing a silicon-containing precursor into the chamber arrangement during deposition of the first boron-doped silicon germanium layer, the second boron-doped silicon germanium layer, and the boron-doped silicon layer. An etchant may be continuously flowed into the chamber arrangement during deposition of the first boron-doped silicon germanium layer, the second boron-doped silicon germanium layer, and the boron-doped silicon layer.

In addition to one or more of the features described above, or as an alternative, further examples of the method may include continuously flowing a boron-containing precursor into the chamber arrangement during deposition of the first boron-doped silicon germanium layer, the second boron-doped silicon germanium layer, ceasing flow of the boron-containing precursor into the chamber arrangement to cease deposition of the second boron-doped silicon germanium layer, and thereafter resuming flow of the boron-containing precursor into the chamber arrangement to deposit the boron-doped silicon layer.

In addition to one or more of the features described above, or as an alternative, further examples of the method may include that seating the substrate includes seating a substrate having an exposed silicon surface portion and an exposed non-silicon or dielectric surface portion in the chamber arrangement. The first boron-doped silicon germanium layer, the second boron-doped silicon germanium layer, and the boron-doped silicon layer may be epitaxial with the exposed silicon surface. Substantially no amorphous or polycrystalline boron-doped silicon germanium material and boron-doped silicon material are deposited onto the exposed non-silicon or dielectric surface portion during the forming of the semiconductor structure.

In addition to one or more of the features described above, or as an alternative, further examples of the method may include depositing a transition layer onto the substrate, and that the first boron-doped silicon germanium layer is deposited onto the transition layer.

A semiconductor structure is provided. The semiconductor structure is formed using the method of forming a semiconductor structure as described above. A germanium concentration of the second boron-doped silicon germanium layer is between about 20 atomic percent and about 45 atomic percent, or between about 25 atomic percent and about 40 atomic percent, or is between about 30 atomic percent and about 35 atomic percent.

A computer program product is provided. The computer program product includes a non-transitory machine-readable medium having instructions recorded in a plurality of program modules that, when read by a processor operably connected to a chamber arrangement of a semiconductor processing system cause the processor to seat a substrate in the chamber arrangement, deposit a first boron-doped silicon germanium layer on the substrate, deposit a second boron-doped silicon germanium layer onto the first boron-doped silicon germanium layer, and deposit a boron-doped silicon layer onto the second boron-doped silicon germanium layer. The first boron-doped silicon germanium layer is deposited at a first boron-doped silicon germanium layer deposition pressure. The second boron-doped silicon germanium layer is deposited at a second boron-doped silicon germanium layer deposition pressure. The first boron-doped silicon germanium layer deposition pressure is greater than the second boron-doped silicon germanium layer deposition pressure.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a semiconductor device being formed on a substrate supported in a chamber arrangement coupling a precursor source to an exhaust source;

FIG. 2 is a schematic view of the precursor source and a controller of the semiconductor processing system of FIG. 1 according to an example of the disclosure, showing the precursor source communicating a precursor to the chamber arrangement to form the semiconductor structure according to instructions recorded on a computer program product;

FIG. 3 is a schematic view of the chamber arrangement of FIG. 1 according to an example of the disclosure, showing the semiconductor structure being formed on the substrate in a chamber arrangement having single-wafer cross-flow architecture;

FIGS. 4-8 are schematic views of a method of forming the semiconductor structure of FIG. 1 according to an example, sequentially showing layers having different compositions being deposited on the substrate while supported in the chamber arrangement; and

FIGS. 9-12 are block diagrams of a method of forming a semiconductor structure, showing operations of the method according to an illustrative and non-limiting example.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

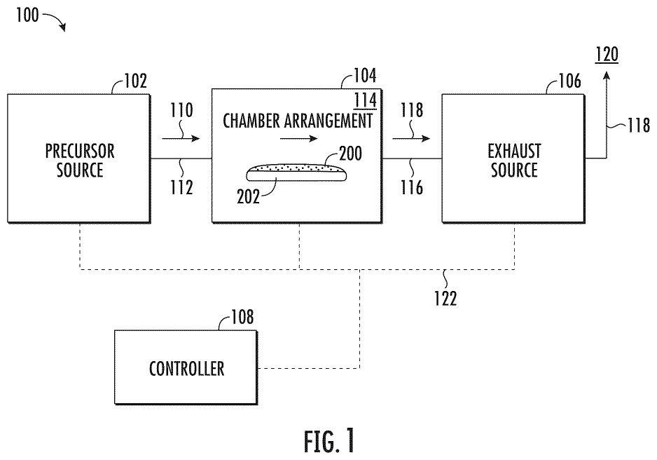

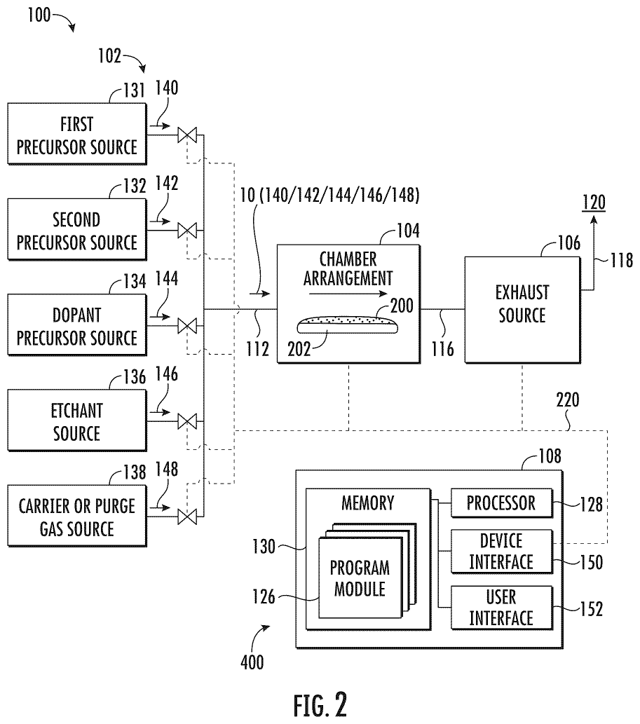

Reference will now be made to the drawings wherein like reference numerals identify similar structural features or aspects of the subject disclosure. For purposes of explanation and illustration, and not limitation, a partial view of an example of a semiconductor processing system in accordance with the present disclosure is shown in FIG. 1 and is designated generally by reference character 100. Other examples of semiconductor processing systems, methods of forming semiconductor structures, and related semiconductor structures and computer program products in accordance with the present disclosure, or aspects thereof, are provided in FIGS. 2-12, as will be described. The systems and methods of the present disclosure may be used to form semiconductor structures used to fabricate semiconductor devices, such as multilayer epitaxial semiconductor structures formed selectively and continuously at high temperature used to fabricate source and drain regions of three-dimensional logic and memory semiconductor devices, though the present disclosure is not limited to any particular semiconductor device structure nor to any particular type of semiconductor device in general.

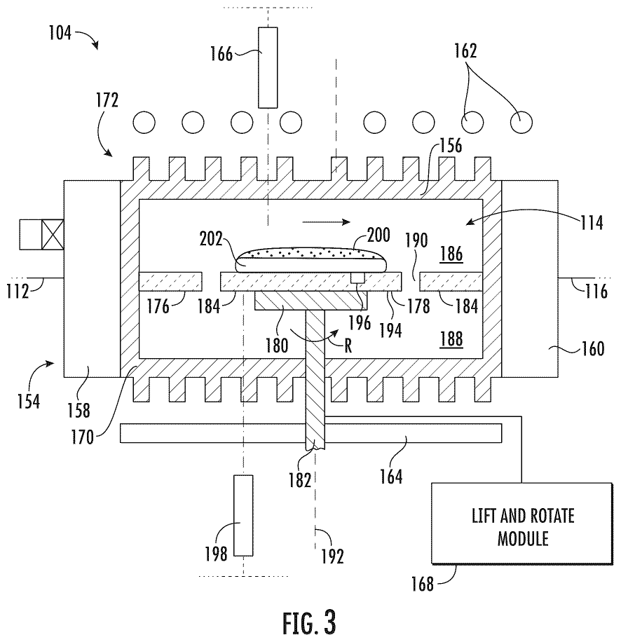

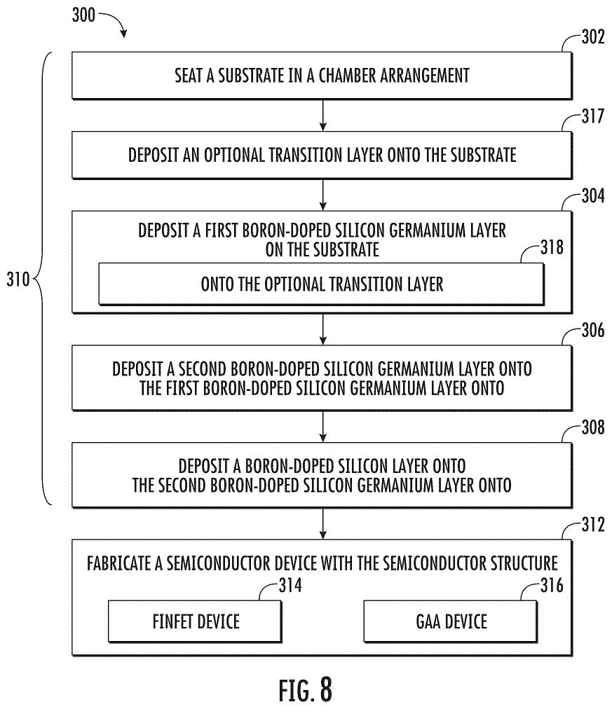

Referring to FIG. 1, the semiconductor processing system 100 is shown. The semiconductor processing system 100 includes a precursor source 102, a chamber arrangement 104, an exhaust source 106, and a controller 108. The precursor source 102 is configured to communicate a precursor 110 to the chamber arrangement 104, and in this respect is coupled to the chamber arrangement 104 by a precursor supply conduit 112. The chamber arrangement 104 is configured to support a substrate 202 during the forming of a semiconductor structure 200 on the substrate 202 using the precursor 110, has a hollow interior 114 configured to contact the substrate with the precursor 110 flowed into the chamber arrangement 104, and is coupled to the exhaust source 106 by an exhaust conduit 116. The exhaust source 106 is configured to communicate a flow of residual precursor and/or reaction products 118 to an external environment 120 outside of the chamber arrangement 104, is fluidly coupled to the external environment 120, and may include one or more of a vacuum pump and an abatement device such as a scrubber and/or a burn box. The controller 108 includes a processor 128 (shown in FIG. 3) operably connected to one or more elements of the semiconductor processing system 100, e.g., the precursor source 102 and/or the chamber arrangement 104 through a wired or wireless link 122, and is configured to cause the semiconductor structure 200 to be formed on the substrate 202 according to instructions contained in a plurality of program modules 126 (shown in FIG. 3) recorded on a non-transitory machine-readable medium of a memory 130 (shown in FIG. 3) that cause the processor to execute operations of a method 300 (shown in FIG. 8) of forming a semiconductor structure, as will be described.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN), and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the precursor source 102 and the controller 108 of the semiconductor processing system 100 are shown according to an example of the disclosure. In this illustrated example the precursor source 102 includes a first precursor source 131, a second precursor source 132, and a dopant-containing precursor source 134. In the illustrated example the precursor source 102 also includes an etchant source 136 and a carrier or purge gas source 138. In certain examples the precursor source 102 may be as shown and described in U.S. Pat. No. 11,053,591 to Ma et al., filed on Aug. 6, 2018, the contents of which are incorporated herein by reference in their entirety. Although shown and described herein as having a specific arrangement, it is to be understood and appreciated that the precursor source 102 may have different arrangements in other examples and remain within the scope of the present disclosure.

The first precursor source 131 may be configured to communicate a first precursor 140 to the chamber arrangement 104. In this respect it is contemplated that the first precursor source 131 include the first precursor 140 and be coupled to the chamber arrangement 104 by the precursor supply conduit 112. In further respect, it is also contemplated that the first precursor source 131 may be coupled to the chamber arrangement 104 by a flow control device, such as through a metering valve and/or a mass flow controller (MFC) device, which may in turn itself be operably associated with the controller 108. In certain examples the first precursor 140 may include one or more silicon-containing precursor. Examples of suitable silicon-containing precursors include non-chlorinated silicon-containing precursors such as silane (SiH₄), disilane (Si₂H₆), and trisilane (Si₃H₈). Examples of suitable chlorinated silicon-containing precursors include dichlorosilane (SiH₂Cl₂), trichlorosilane (SiHCl₃), and silicon tetrachloride (SiCl₄).

The second precursor source 132 may be similar to the first precursor source 131 and is additionally configured to communicate one or more second precursor 142 to the chamber arrangement 104. In this respect the second precursor source 132 may by coupled to the chamber arrangement 104 by the precursor supply conduit 112. In further respect the second precursor source 132 may be coupled to the chamber arrangement 104 by a flow control device such as second precursor metering valve and/or a second precursor MFC device operably associated with the controller 108. In certain examples the second precursor 142 may include a metal, such as germanium (Ge), gallium (Ga), or aluminum (Al). Examples of suitable germanium-containing precursors include germane (GeH₄), germanium tetrachloride (GeCl₄), and digermane (Ge₂H₆).

The dopant-containing precursor source 134 may be configured to communicate one or more dopant-containing precursor 144 to the chamber arrangement 104 and in this respect may be coupled to the chamber arrangement 104 by the precursor supply conduit 112. In certain examples the dopant-containing precursor 144 may include a p-type dopant. Examples of suitable p-type dopants include boron (B), and in this respect the dopant-containing precursor 144 may include a boron-containing precursor such as diborane (B₂H₆). In accordance with certain examples, the dopant-containing precursor 144 may include an n-type dopant, such as arsenic (As) or phosphorus (P), the dopant-containing precursor 144 including arsine (AsH₃) and/or phosphine (PH₃) in such examples.

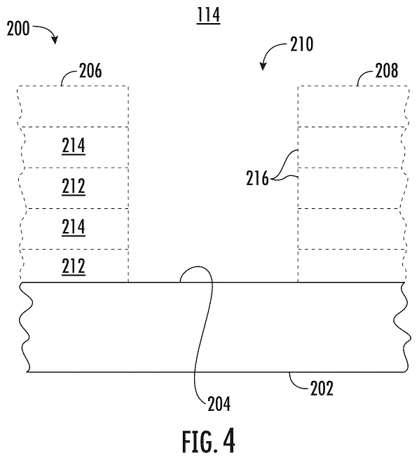

The etchant source 136 may be configured to communicate an etchant 146 to the chamber arrangement 104, for example through the precursor supply conduit 112 and/or through a separated supply conduit. In certain examples the etchant source 136 may be coupled to the chamber arrangement 104 through a flow control device, such as an etchant metering valve and/or an etchant supply MFC device operably associated with the controller 108 and include the etchant 146. In accordance with certain examples, the etchant may be co-flowed to the chamber arrangement 104 with one or more of the first precursor 140, the second precursor 142, and/or the dopant-containing precursor 144, for example to provide selectivity of deposition of the one or more layers of the semiconductor structure 200 on (or overlaying) a silicon surface portion 204 (shown in FIG. 4) of the substrate 202 relative to a non-silicon or dielectric surface portion 206 (shown in FIG. 4) of the substrate 202. Non-limiting examples of suitable etchants include halide-containing etchants, such as chlorine-containing etchants like hydrochloric acid (HCl) and chlorine (Cl₂) gas and fluorine-containing etchants like hydrogen fluoride (HF) and fluorine (F₂) gas.

The carrier or purge gas source 138 may be configured to communicate a carrier or purge gas 148 to the chamber arrangement 104, for example independent of one or more of the aforementioned precursors and etchants (e.g., as a purge gas) as well as intermixed with one or more of the aforementioned precursors and etchants through the precursor supply conduit 112. In this respect the carrier or purge gas 148 may be employed as a diluent and/or carrier of one or more of the precursors and/or etchants communicated to the chamber arrangement 104. Non-limiting examples of carrier or purge gases include hydrogen (H₂) gas as well as inert gases like nitrogen (N₂) gas, argon (Ar) gas, helium (He) gas, krypton (Kr) gas as well as mixtures including one of the aforementioned gases.

In the illustrated example the controller 108 includes a device interface 150, the processor 128, a user interface 152, and the memory 130. The device interface 150 couples the processor 128 to one or more of the precursor source 102, the chamber arrangement 104, and/or the exhaust source 106. The processor 128 is disposed in communication with the user interface 152, for example to receive a user input and/or provide a user output therethrough, and the memory 130. The memory 130 includes a non-transitory machine-readable medium having the plurality of program modules 126 recorded thereon. It is contemplated that the plurality of program modules 126 contain instructions that, when read by the processor 128, cause the processor 128 to execute certain operations, and in this respect may be included in a computer program product 400. Among the operations are the operations of the method 300 (shown in FIG. 8), as will be described. Although shown and described herein as having a specific architecture it is to be understood and appreciated that the controller 108 may have different architectures in other examples, for example a distributed computing architecture, and remain within the scope of the present disclosure.

With reference to FIG. 3, the chamber arrangement 104 is shown according to an example of the disclosure. In the illustrated example the chamber arrangement 104 is a gas-phase chamber arrangement having a single-wafer cross-flow architecture 154 and includes a chamber body 156, an injection flange 158, and an exhaust flange 160. In the illustrated example the chamber arrangement 104 also includes an upper heater element array 162, a lower heater element array 164, an upper pyrometer 166, and a lift and rotate module 168. Although shown and described herein as having a specific arrangement and including certain elements, it is to be understood and appreciated that the chamber arrangement 104 may have a different arrangement in other examples (e.g., a multi-wafer arrangement), and/or include additional elements as well as exclude elements shown and described herein, and remain within the scope of the disclosure.

The chamber body 156 is formed from a transparent material 170, which bounds the hollow interior 114 of the chamber body 156, and which further extends between an injection end 172 and a longitudinally opposite exhaust end 174. The exhaust flange 160 abuts the exhaust end 174 of the chamber body 156, is coupled to the exhaust source 106 (shown in FIG. 1) by the exhaust conduit 116, and fluidly couples the hollow interior 114 of the chamber body 156 to the exhaust source 106. The injection flange 158 abuts the injection end 172 of the chamber body 156, is coupled to the precursor source 102 (shown in FIG. 1) by the precursor supply conduit 112, and fluidly couples the precursor source 102 to the hollow interior 114 of the chamber body 156. It is contemplated that the upper heater element array 162 may include a plurality of heater elements, for example linear or bulb-type filament lamps, and is configured to heat the substrate 202 using radiant energy (e.g., electromagnetic radiation within an infrared waveband) communicated into the hollow interior 114 of the chamber body 156 through the transparent material 170 forming the chamber body 156.

The lower heater element array 164 may be similar to the upper heater element array 162 and is additionally supported below the chamber body 156. The lower heater element array 164 may further be configured to heat the substrate 202 using radiant energy communicated into the hollow interior 114 of the chamber body 156 through the transparent material 170 forming the chamber body 156. It is contemplated that the upper pyrometer 166 be supported outside of the chamber body 156 (e.g., above relative to gravity) and be operably coupled to one or more of the upper heater element array 162 and the lower heater element array 164 by the controller 108. In this respect it is contemplated that the upper pyrometer 166 acquire temperature of the substrate 202 (or structure within the hollow interior 114 of the chamber body 156) using electromagnetic radiation emitted thereby and communicated to the upper pyrometer 166 through the transparent material 170 forming the chamber body 156. In certain examples the transparent material 170 may include (or consist of or consist essentially of) a ceramic material, such as quartz or sapphire by way of non-limiting example.

It is contemplated that the chamber arrangement 104 include a divider 176, a substrate support 178, a support member 180, and a shaft member 182. The divider 176 may be formed from an opaque material 184 (e.g., a material opaque to electromagnetic radiation within an infrared waveband such as silicon carbide or a carbonaceous material like graphite or pyrolytic carbon with a silicon carbide coating), is seated within the hollow interior 114 of the chamber body 156, and divides the hollow interior 114 of the chamber body 156 into an upper chamber 186 and a lower chamber 188. The divider 176 may further define a divider aperture 190 therethrough, the divider aperture 190 in turn fluidly coupling the lower chamber 188 of the chamber body 156 to the upper chamber 186 of the chamber body 156. It is further contemplated that the substrate support 178 may be supported (at least in part) within the divider aperture 190 for rotation about a rotation axis 192, that the substrate support 178 may be formed from the opaque material 184, and that the substrate support 178 be configured to support the substrate 202 during the forming of the semiconductor structure 200 on the substrate 202.

The support member 180 may be arranged within the lower chamber 188 of the chamber body 156 and along the rotation axis 192, may be fixed in rotation R relative to the substrate support 178 about the rotation axis 192, and couple the substrate support 178 to the shaft member 182. It is contemplated that the shaft member 182 in turn may be fixed in rotation R about the rotation axis 192 relative to the support member 180, be arranged along the rotation axis 192 and extend through a lower wall of the chamber body 156, and operably couple the lift and rotate module 168 to the substrate support 178 through the support member 180. The lift and rotate module 168 is in turn configured to rotate the substrate support 178 about the rotation axis 192 through the shaft member 182 and the support member 180 as well as seat and unseat substrates (e.g., the substrate 202) from the substrate support 178, for example using one or more lift pins carried by the substrate support 178. In this respect the lift and rotate module 168 may be as shown and described in U.S. Patent Application Publication No. 2020/0365444 A1, filed on Jul. 31, 2020, the contents of which are incorporated herein by reference in its entirety. In certain examples one or more of the support member 180 and the shaft member 182 may be formed from transparent material, such as the transparent material 170.

With reference to FIGS. 4-8, formation of the semiconductor structure 200 on the substrate 202 is shown according to the present disclosure. As shown in FIG. 4, formation of the semiconductor structure 200 is accomplished by seating the substrate 202 within the interior 114 of the chamber body 156 (shown in FIG. 3) included in the chamber arrangement 104 (shown in FIG. 1) of the semiconductor processing system 100 (shown in FIG. 1). In certain examples the substrate 202 may have an exposed silicon surface portion 204 and an exposed non-silicon or dielectric surface portion 206, such as an exposed dielectric surface portion formed (at least in part) of silicon nitride. In such examples the exposed non-silicon or dielectric surface portion 206 may bound (at least in part) the exposed silicon surface portion 204. In such examples the exposed silicon surface portion 204 may be one of a plurality of exposed silicon surface portions 204 defined on an upper surface 208 of the substrate 202, and the exposed non-silicon or dielectric surface portion 206 may be one of a plurality of exposed non-silicon or dielectric surface portion 206 defined on the upper surface 208 of the substrate 202. It is contemplated that the exposed silicon surface portion 204 may be defined within a recess 210 within the upper surface 208 of the substrate 202. In this respect the recess 210 may be bounded by a plurality of exposed silicon germanium surfaces 212 and exposed silicon surface portions 214 of alternating silicon germanium and silicon layer pairs 216 deposited onto (or on) an upper surface of the substrate 202.

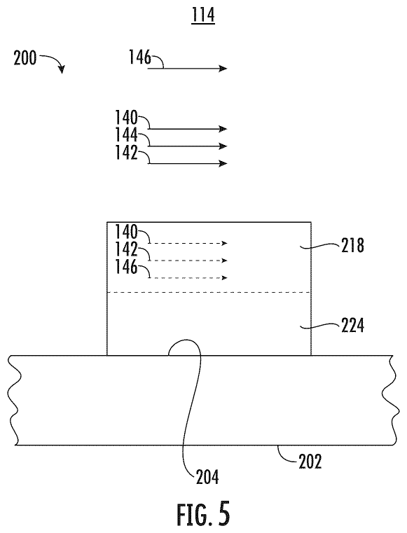

As shown in FIG. 5, forming the semiconductor structure 200 may include depositing a first boron-doped silicon germanium layer 218 on the substrate 202. Depositing the first boron-doped silicon germanium layer 218 may include throttling pressure within the interior 114 of the chamber arrangement 104 (shown in FIG. 1) to a predetermined first boron-doped silicon germanium layer deposition pressure. For example, pressure within the interior 114 of the chamber arrangement 104 may be throttled to a predetermined first boron-doped silicon germanium layer deposition pressure that is between about 10 Torr and about 300 Torr, or between about 10 Torr and about 200 Torr, or between about 10 Torr and about 100 Torr, or even that is between about 50 Torr and about 100 Torr. Pressure within the interior 114 of the chamber arrangement 104 may remain constant (e.g., unchanged) at the predetermined first boron-doped silicon germanium layer deposition pressure for substantially an entirety of a first boron-doped silicon germanium layer deposition interval, for example a first boron-doped silicon germanium layer deposition interval that is between about 10 seconds and about 100 seconds, or between about 20 seconds and about 100 seconds, or between about 40 seconds and about 100 seconds, or even that is between about 60 seconds and about 100 seconds.

It is contemplated that depositing the first boron-doped silicon germanium layer 218 includes heating the substrate to a predetermined first boron-doped silicon germanium layer deposition temperature. In this respect the substrate 202 may be heated to a predetermined first boron-doped silicon germanium layer deposition temperature that is between about 500 degrees Celsius and about 1000 degrees Celsius, or between about 500 degrees Celsius and about 900 degrees Celsius, or between about 500 degrees Celsius and about 700 degrees Celsius, or even that is between about 600 degrees Celsius and about 700 degrees Celsius. Temperature of the substrate may remain constant at the predetermined first boron-doped silicon germanium layer deposition temperature for substantially all of the entirety of the first boron-doped silicon germanium layer deposition interval.

In certain examples temperature of the substrate may be controlled by throttling power applied to heater elements of the upper heater element array 162 (shown in FIG. 3) and/or the lower heater element array 164 (shown in FIG. 3) of the chamber arrangement 104 using a temperature measurement acquired using a non-contact temperature sensor and/or a contact temperature sensor. For example, the upper pyrometer 166 (shown in FIG. 3) may acquire temperature of the first boron-doped silicon germanium layer using electromagnetic radiation emitted by the first boron-doped silicon germanium layer during deposition on the substrate 202. Alternatively (or additionally) power to the upper heater element array 162 and/or the lower heater element array 164 may be throttled using temperature acquired using electromagnetic radiation emitted by a lower surface 194 (shown in FIG. 3) of the substrate support 178 (shown in FIG. 3) during deposition of the first boron-doped silicon germanium layer on the substrate 202, for example using a lower pyrometer 198 (shown in FIG. 3). It is also contemplated that power applied to heater elements of one or more of the upper heater element array 162 and the lower heater element array 164 may be controlled using a temperature measurement of the substrate support 178 acquired using the thermocouple 196 (shown in FIG. 3), which may be in intimate mechanical contact with the lower surface 194 of the substrate support 178, and remain within the scope of the present disclosure. Advantageously, controlling temperature of the substrate 202 using the upper pyrometer 166 may limit (or eliminate) temperature overshoot during ramping to the first deposition temperature employed to form the semiconductor structure 200, e.g., the first boron-doped silicon germanium deposition temperature, due to the real-time nature of temperature measurements acquired using electromagnetic radiation emitted by the substrate 202. Limiting overshoot in turn enables ramping more rapidly, limiting time required to form the semiconductor structure 200, increasing throughput of the semiconductor processing system 100 (shown in FIG. 1) employed to form the semiconductor structure 200.

It is further contemplated that depositing the first boron-doped silicon germanium layer 218 may include flowing the first precursor 140 into the interior 114 of the chamber arrangement 104 (shown in FIG. 1), such as a silicon-containing precursor like silane (SiH₄) or dichlorosilane (SiH₂Cl₂). Depositing the first boron-doped silicon germanium layer 218 on the substrate 202 may also include flowing (e.g., co-flowing) the second precursor 142 into the interior 114 of the chamber arrangement 104, such as a germanium-containing precursor like germane (GeH₄) or digermane (Ge₂H₆). Depositing the first boron-doped silicon germanium layer 218 may further include flowing (e.g., co-flowing) the dopant-containing precursor 144 into the interior 114 of the chamber arrangement 104, such as a boron-containing precursor like diborane (B₂H₆). Depositing the first boron-doped silicon germanium layer 218 may additionally include flowing (e.g., co-flowing) the etchant 146 into the interior 114 of the chamber arrangement 104, such as a chlorinated etchant like hydrochloric acid (HCl).

In certain examples one or more of the first precursor 140, the second precursor 142, the dopant-containing precursor 144, and the etchant 146 may be flowed into the interior 114 of the chamber arrangement 104 continuously and without interruption during substantially the entirety of the first boron-doped silicon germanium layer deposition interval. In accordance with certain examples, deposition of the first boron-doped silicon germanium layer 218 may be accomplished such that the first boron-doped silicon germanium layer 218 is epitaxial with the silicon surface portion 204 of the substrate 202. It is also contemplated that the first boron-doped silicon germanium layer 218 may be deposited such that substantially no material forms on the exposed non-silicon or dielectric surface portion 206 (shown in FIG. 4) of the substrate 202. Advantageously, forming the first boron-doped silicon germanium layer 218 continuously, e.g., without employing a cycle deposition and etch technique, and without depositing a boron-doped silicon germanium layer onto the exposed non-silicon or dielectric surface portion 206 of the substrate 202 may limit time required to form the semiconductor structure 200, increasing throughput of the semiconductor processing system 100 employed to form the semiconductor structure 200.

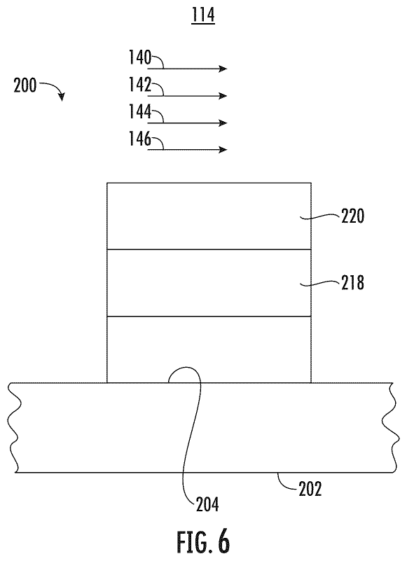

As shown in FIG. 6, forming the semiconductor structure 200 may include depositing a second boron-doped silicon germanium layer 220 onto (e.g., without an intervening layer) the first boron-doped silicon germanium layer 218. Depositing the second boron-doped silicon germanium layer 220 may include throttling pressure within the interior 114 of the chamber arrangement 104 (shown in FIG. 1) to a predetermined second boron-doped silicon germanium layer deposition pressure. In this respect, pressure within the interior 114 of the chamber arrangement 104 may be throttled to a predetermined second boron-doped silicon germanium layer deposition pressure that differs from (e.g., is less than) the predetermined first boron-doped silicon germanium layer deposition pressure.

In certain examples the second boron-doped silicon germanium layer deposition pressure may be between about 10 Torr and about 100 Torr, or between about 10 Torr and about 80 Torr, or between about 10 Torr and about 60 Torr, or between about 25 Torr and about 40 Torr. In certain examples, a ratio of the predetermined first boron-doped silicon germanium layer deposition pressure to the predetermined second boron-doped silicon germanium layer deposition pressure may between about 2:1 and about 10:1, or between about 2:1 and about 8:1, or between about 2:1 and about 6:1, or even between about 2:1 and about 3:1. Advantageously, deposition pressures and ratios within these ratios may enable deposition of the second boron-doped silicon germanium layer 220 epitaxially onto the first boron-doped silicon germanium layer 218 in a regime that is selective relative to the exposed non-silicon or dielectric surface portion 206 of the substrate 202 continuously, limiting time required to form the semiconductor structure 200. In accordance with certain examples, pressure within the interior 114 of the chamber arrangement 104 may remain constant (e.g., unchanged) at the predetermined second boron-doped silicon germanium layer deposition pressure for substantially an entirety of a second boron-doped silicon germanium layer deposition interval, for example during a second boron-doped silicon germanium layer deposition interval that is between about 10 seconds and about 100 seconds, or between about 20 seconds and about 100 seconds, or between about 40 seconds and about 100 seconds, or even that is between about 60 seconds and about 100 seconds.

It is contemplated that depositing the second boron-doped silicon germanium layer 220 include heating the substrate to a predetermined second boron-doped silicon germanium layer deposition temperature. In this respect the substrate 202 may be heated to a predetermined second boron-doped silicon germanium layer deposition temperature that is between about 500 degrees Celsius and about 1000 degrees Celsius, or between about 500 degrees Celsius and about 900 degrees Celsius, or between about 500 degrees Celsius and about 700 degrees Celsius, or is between about 600 degrees Celsius and about 700 degrees Celsius. Temperature of the substrate 202 may remain constant at the predetermined second boron-doped silicon germanium layer deposition temperature for substantially all of the entirety of the second boron-doped silicon germanium layer deposition interval. In certain examples, the predetermined second boron-doped silicon germanium layer deposition temperature may be substantially equivalent to the predetermined first boron-doped silicon germanium layer deposition temperature.

In accordance with certain examples, temperature of the substrate 202 may be controlled during deposition of the second boron-doped silicon germanium layer 220 onto the first boron-doped silicon germanium layer 218 by throttling power applied to heater elements of the upper heater element array 162 (shown in FIG. 3) and/or the lower heater element array 164 (shown in FIG. 3) of the chamber arrangement 104 using a temperature measurement acquired using a non-contact temperature sensor and/or a contact temperature sensor. For example, the upper pyrometer 166 (shown in FIG. 3) may acquire temperature of the second boron-doped silicon germanium layer using electromagnetic radiation emitted by the second boron-doped silicon germanium layer 220 during deposition onto the first boron-doped silicon germanium layer 218. Alternatively (or additionally) power to the upper heater element array 162 and/or the lower heater element array 164 may be throttled using temperature acquired using electromagnetic radiation emitted by a lower surface 194 of the substrate support 178 (shown in FIG. 3) during deposition of the second boron-doped silicon germanium layer 220 onto the first boron-doped silicon germanium layer 218. In this respect power applied to heater elements of one or more of the upper heater element array 162 and the lower heater element array 164 may be controlled using a temperature measurement of the substrate support 178 acquired using the lower pyrometer 198 (shown in FIG. 3) and/or thermocouple 196 (shown in FIG. 3), which in turn may be in intimate mechanical contact with the lower surface 194 of the substrate support 178 during deposition of the second boron-doped silicon germanium layer 220 onto the first boron-doped silicon germanium layer 218.

It is contemplated that depositing the second boron-doped silicon germanium layer 220 onto the first boron-doped silicon germanium layer 218 include flowing the first precursor 140 into the interior 114 of the chamber arrangement 104 (shown in FIG. 1), such as a silicon-containing precursor like silane (SiH₄) and/or dichlorosilane (SiH₂Cl₂). Depositing the second boron-doped silicon germanium layer 220 may also include flowing the second precursor 142 into the interior 114 of the chamber arrangement 104, such as a germanium-containing precursor like germane (GeH₄) or digermane (Ge₂H₆). Depositing the second boron-doped silicon germanium layer 220 may further include flowing the dopant-containing precursor 144 into the interior 114 of the chamber arrangement 104, such as a boron-containing precursor like diborane (B₂H₆). Depositing the first boron-doped silicon germanium layer may additionally include flowing the etchant 146 into the interior 114 of the chamber arrangement 104, such as a chlorinated etchant like hydrochloric acid (HCl). It is contemplated that the aforementioned fluids may be introduced into the interior 114 of the chamber arrangement 104 in a gaseous state, and that one or more of the aforementioned fluids may be intermixed with the carrier or purge gas 148.

In certain examples one or more of the first precursor 140, the second precursor 142, the dopant-containing precursor 144, and the etchant 146 may be flowed into the interior 114 of the chamber arrangement continuously and without interruption during substantially the entirety of the second boron-doped silicon germanium layer deposition interval. In accordance with certain examples, deposition of the second boron-doped silicon germanium layer 220 may be accomplished such that the second boron-doped silicon germanium layer 220 is epitaxial with the first boron-doped silicon germanium layer 218. It is also contemplated that the second boron-doped silicon germanium layer 220 may also be deposited such that substantially no material forms on the exposed non-silicon or dielectric surface portion 206 of the substrate 202. Advantageously, depositing the second boron-doped silicon germanium layer 220 onto the first boron-doped silicon germanium layer 218 continuously, e.g., without employing a cycle deposition and etch technique, and without depositing a boron-doped silicon germanium layer onto the exposed non-silicon or dielectric surface portion 206 of the substrate 202 may further limit time required to form the semiconductor structure 200, further increasing throughput of the semiconductor processing system 100 employed to form the semiconductor structure 200.

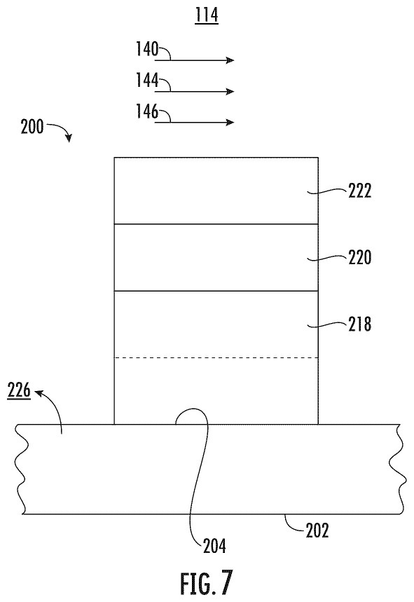

As shown in FIG. 7, forming the semiconductor structure 200 may further include depositing a boron-doped silicon layer 222 onto the second boron-doped silicon germanium layer 220. Deposition of the boron-doped silicon layer 222 may be accomplished by throttling pressure within the interior 114 of the chamber arrangement 104 (shown in FIG. 1) to a predetermined boron-doped silicon layer deposition pressure relative to either (or both) the predetermined first boron-doped silicon germanium layer deposition pressure and the predetermined second boron-doped silicon germanium layer deposition pressure. In this respect pressure within the interior 114 of the chamber arrangement 104 may be throttled to a predetermined boron-doped silicon layer deposition pressure that is greater than the predetermined second boron-doped silicon germanium layer deposition pressure. Pressure within the interior 114 of the chamber arrangement 104 may be throttled to a predetermined boron-doped silicon layer deposition pressure that is less than the predetermined first boron-doped silicon germanium layer deposition pressure. In further respect, pressure within the interior 114 of the chamber arrangement 104 may be throttled to a predetermined boron-doped silicon layer deposition pressure from the predetermined first boron-doped silicon germanium layer deposition pressure, for example that is both less than the predetermined first boron-doped silicon germanium layer deposition pressure and greater than the predetermined second boron-doped silicon germanium layer deposition pressure.

In certain examples the boron-doped silicon layer deposition pressure may be between about 10 Torr and about 100 Torr, or between about 10 Torr and about 80 Torr, or between about 10 Torr and about 60 Torr, or is between about 10 Torr and about 40 Torr. In accordance with certain examples a ratio of the predetermined first boron-doped silicon germanium layer deposition pressure to the boron-doped silicon layer deposition pressure may be between about 2:1 and about 10:1, or between about 2:1 and about 8:1, or between about 2:1 and about 6:1, or even that is between about 2:1 and 4:1. It is contemplated that a ratio of the predetermined boron-doped silicon layer deposition pressure to the predetermined second boron-doped silicon germanium layer deposition pressure may be between about 1.1:10 and about 1.1:5, or between about 1.1:1 and about 4:1, or between about 1.1:1 and about 3:1, or even that is between about 1.1:1 and about 2:1. It is also contemplated that, in accordance with certain examples, pressure within the interior 114 of the chamber arrangement 104 (shown in FIG. 1) may remain constant (e.g., unchanged) during substantially an entirety of a boron-doped silicon layer deposition interval, for example during a boron-doped silicon layer deposition interval that is between about 10 seconds and about 200 seconds, or between about 10 seconds and about 80 seconds, or between about 10 seconds and about 160 seconds, or even that is between about 10 seconds and about 140 seconds. Advantageously, deposition pressures and ratios within these ratios may enable deposition of the boron-doped silicon layer 222 epitaxially onto the second boron-doped silicon germanium layer 220 in a regime that is selective relative to the exposed non-silicon or dielectric surface portion 206 of the substrate 202 continuously, limiting time required to form the semiconductor structure 200.

Depositing the boron-doped silicon layer 222 may include heating the substrate 202 to a predetermined boron-doped silicon layer deposition temperature. In certain examples the substrate 202 may be heated to a predetermined boron-doped silicon layer deposition temperature that is between about 500 degrees Celsius and about 1000 degrees Celsius, or between about 500 degrees Celsius and about 900 degrees Celsius, or between about 500 degrees Celsius and about 700 degrees Celsius, or even that is between about 600 degrees Celsius and about 700 degrees Celsius. In accordance with certain examples, the boron-doped silicon layer deposition temperature may be substantially equivalent to the predetermined first boron-doped silicon germanium layer deposition temperature, that is substantially equivalent to the predetermined second boron-doped silicon germanium layer deposition temperature, or that is substantially equivalent to both the predetermined first boron-doped silicon germanium layer deposition temperature and the predetermined second boron-doped silicon germanium layer deposition temperature. It is also contemplated that temperature of the substrate may be maintained at the predetermined boron-doped silicon layer deposition temperature during substantially the entirety of the boron-doped silicon layer deposition interval. Advantageously, depositing the boron-doped silicon layer 222 at the same temperature as the second boron-doped silicon germanium layer 220 may also limit time required to form the semiconductor structure 200, for example by limiting (or eliminating) time required to stabilize temperature of the substrate 202 prior to deposition of the boron-doped silicon layer 222.

Temperature of the substrate 202 may be controlled during deposition of the boron-doped silicon layer 222 onto the second boron-doped silicon germanium layer 220 by throttling power applied to heater elements of the upper heater element array 162 (shown in FIG. 3) and/or the lower heater element array 164 (shown in FIG. 3) of the chamber arrangement 104. In this respect a temperature measurement indicative of temperature of the substrate 202 may be acquired using a non-contact temperature sensor and/or a contact temperature sensor. In certain examples the upper pyrometer 166 (shown in FIG. 3) may be employed to acquire temperature of the boron-doped silicon layer 222 using electromagnetic radiation emitted by the boron-doped silicon layer 222 during deposition of the boron-doped silicon layer. Alternatively (or additionally) power to the upper heater element array 162 and/or the lower heater element array 164 may be throttled using temperature acquired using electromagnetic radiation emitted by a lower surface 194 (shown in FIG. 3) of the substrate support 178 (shown in FIG. 3) during deposition of the boron-doped silicon layer 222 onto the second boron-doped silicon germanium layer 220 using the lower pyrometer 198 (shown in FIG. 3) supported below the chamber body 156 (shown in FIG. 3). It is also contemplated that power applied to the upper heater element array 162 and/or the lower heater element array 164 of the chamber arrangement 104 may additionally (or alternatively) be controlled using a temperature measurement of the substrate support 178 acquired using the thermocouple 196 (shown in FIG. 3), which may in turn be in intimate mechanical contact with the lower surface 194 of the substrate support 178, and remain within the scope of the present disclosure.

Deposition of the boron-doped silicon layer 222 onto the second boron-doped silicon germanium layer 220 may include flowing the first precursor 140 into the interior 114 of the chamber arrangement 104 (shown in FIG. 1), such as a silicon-containing precursor like silane (SiH₄) and/or dichlorosilane (SiH₂Cl₂). Deposition of the boron-doped silicon layer 222 onto the second boron-doped silicon germanium layer 220 may further include flowing the dopant-containing precursor 144 into the interior 114 of the chamber arrangement 104, such as a boron-containing precursor like diborane (B₂H₆). Deposition of the boron-doped silicon layer 222 onto the second boron-doped silicon germanium layer 220 may additionally include flowing the etchant 146 into the interior 114 of the chamber arrangement 104, such as a chlorinated etchant like hydrochloric acid (HCl). In certain examples a common first precursor may be flowed into the chamber arrangement 104 to deposit each of the first boron-doped silicon germanium layer 218, the second boron-doped silicon germanium layer 220, and the boron-doped silicon layer 222, such as dichlorosilane (SiH₂Cl₂). In accordance with certain examples, a common dopant-containing material precursor may be flowed into the chamber arrangement 104 to deposit each of the first boron-doped silicon germanium layer 218 the second boron-doped silicon germanium layer 220, and the boron-doped silicon layer 222, such as diborane (B₂H₆). It is also contemplated that a common etchant may be flowed into the chamber arrangement 104 during deposition of each of the first boron-doped silicon germanium layer 218, the second boron-doped silicon germanium layer 220, and the boron-doped silicon layer 222, such as hydrochloric acid (HCl). Advantageously, this may limit complexity of the semiconductor processing system 100 (shown in FIG. 1) employed to form the semiconductor structure 200.

In certain examples the first precursor 140, the dopant-containing precursor 144, and the etchant 146 may be flowed into the chamber arrangement 104 (shown in FIG. 1) as a gas. In accordance with certain examples, one or more of the first precursor 140, the dopant-containing precursor 144, and the etchant 146 may be flowed into the chamber arrangement 104 intermixed with the carrier or purge gas 148. It is also contemplated that, in accordance with certain examples, either (or both) the first precursor 140, the dopant-containing precursor 144, and the etchant 146 may be flowed into the interior 114 of the chamber arrangement continuously and without interruption during substantially the entirety of the boron-doped silicon layer deposition interval. The boron-doped silicon layer 222 may be deposited such that the boron-doped silicon layer 222 is epitaxial with the second boron-doped silicon germanium layer 220. The boron-doped silicon layer 222 may further be deposited such that substantially no boron-doped material is deposited onto the exposed non-silicon or dielectric surface portion 206 of the substrate 202. In accordance with certain examples, deposition of the second boron-doped silicon germanium layer 220 may be accomplished such that the second boron-doped silicon germanium layer 220 is epitaxial with the first boron-doped silicon germanium layer 218. It is further contemplated that the substrate 202 may thereafter be removed from the chamber arrangement 104 and a semiconductor device formed using the semiconductor structure 200, for example a logic or memory semiconductor device having a three-dimensional architecture such as a FinFET architecture or a gate-all-around architecture, as shown in FIG. 7 with arrow 226. Advantageously, depositing the boron-doped silicon layer 222 onto the second boron-doped silicon germanium layer 220 continuously, e.g., without employing a cycle deposition and etch technique, and without depositing boron-doped silicon material onto the exposed non-silicon or dielectric surface portion 206 of the substrate 202 may additionally limit time required to form the semiconductor structure 200, additionally increasing throughput of the semiconductor processing system 100 used to form the semiconductor structure 200.

With continuing reference to FIG. 5, it is contemplated that the semiconductor structure 200 may include an optional transition layer 224, for example a germanium concentration grading layer. The optional transition layer 224 may be deposited onto the silicon surface portion 204, for example within the recess 210 (shown in FIG. 4), and be formed by flowing the first precursor 140 and the second precursor 142 into the interior 114 of the chamber arrangement 104 (shown in FIG. 1). It is contemplated that the first precursor 140 may include silicon (Si), that the second precursor may include germanium (Ge), and that the optional transition layer 224 may include (or consist of or consist essentially of) silicon germanium epitaxial with the silicon surface portion 204 of the substrate 202. Deposition of the optional transition layer 224 may include throttling pressure within the interior 114 of the chamber arrangement 104 to a transition layer deposition pressure, for example to transition layer deposition pressure that is substantially equivalent to the first boron-doped silicon germanium layer deposition pressure. Deposition of the optional transition layer 224 may include heating the substrate 202 to a transition layer deposition temperature, for example to a transition layer deposition temperature that is substantially equivalent to the predetermined first boron-doped silicon germanium layer deposition temperature.

In certain examples deposition of the optional transition layer 224 may include flowing (e.g., co-flowing) the etchant 146 into the interior 114 of the chamber arrangement 104 during deposition of the optional transition layer 224. Advantageously, flowing the etchant 146 into the chamber arrangement 104 may render deposition of the optional transition layer 224 selective to the silicon surface portion 204 of the substrate 202, limiting (or preventing) deposition of silicon germanium material onto the exposed non-silicon or dielectric surface portion 206 of the substrate 202, limiting time required for the forming of the semiconductor structure 200 by avoiding the need to remove such silicon germanium material from the exposed non-silicon or dielectric surface portion 206 in a separate removal operation and/or avoiding the need to employ a cyclic deposition and etch technique to deposit the optional transition layer 224.

In certain examples temperature of the substrate 202 may be controlled using a non-contact temperature sensor. For example, electromagnetic radiation emitted by the optional transition layer 224 during deposition of the optional transition layer 224 may be received at the upper pyrometer 166 (shown in FIG. 3) and used to control power applied to the upper heater element array 162 (shown in FIG. 3) and/or the lower heater element array 164 (shown in FIG. 3). Alternatively (or additionally), temperature of the substrate 202 may be controlled using electromagnetic radiation emitted by the substrate support 178 (shown in FIG. 3) and received at the lower pyrometer 198 (shown in FIG. 3) to control power applied to the upper heater element array 162 and/or the lower heater element array 164 during deposition of the optional transition layer 224 onto the substrate 202. It is also contemplated that temperature of the substrate 202 may be controlled using a temperature measurement acquired using a contact temperature sensor during deposition of the optional transition layer 224, for example using the thermocouple 196 (shown in FIG. 3) to control power applied to the upper heater element array 162 and/or the lower heater element array 164.

In certain examples the optional transition layer 224 may have a germanium concentration that is less than a germanium concentration of the first boron-doped silicon germanium layer 218 and/or the second boron-doped silicon germanium layer 220. For example, the optional transition layer 224 may have a germanium concentration that is between about 1 atomic percent and about 20 atomic percent, or between about 1 atomic percent and about 15 atomic percent, or even between about 1 atomic percent and about 10 atomic percent; the first boron-doped silicon germanium layer 218 may have a germanium concentration that is between about 10 atomic percent and about 30 atomic percent, or between about 10 atomic percent and about 25 atomic percent, or even that is between about 10 atomic percent and about 20 atomic percent; and the second boron-doped silicon germanium layer 220 may have a germanium concentration that is between about 20 atomic percent and about 45 atomic percent, or between about 25 atomic percent and about 40 atomic percent, or even that is between about 30 atomic percent and about 35 atomic percent. Advantageously, inclusion of the optional transition layer 224 may enable the second boron-doped silicon germanium layer 220 to have a relatively high germanium concentration, for example due to graduation of germanium concentration within a thickness of the semiconductor structure 200. As will be appreciated by those of skill in the art in view of the present disclosure, relatively high germanium concentration may improve electrical properties of the semiconductor structure 200, such as by enhancing hole mobility within the semiconductor structure 200.

With reference to FIGS. 8-12, the method 300 of forming a semiconductor structure, e.g., the semiconductor structure 200 (shown in FIG. 1), is shown according to an example of the disclosure. As shown in FIG. 8, the method 300 includes seating a substrate in a chamber arrangement, e.g., seating the substrate 202 (shown in FIG. 1) in the chamber arrangement 104 (shown in FIG. 1), as shown with box 302. Once seated in the chamber arrangement a first boron-doped silicon germanium layer is deposited on the substrate, e.g., the first boron-doped silicon germanium layer 218 (shown in FIG. 5), as shown with box 304. A second boron-doped silicon germanium layer is then deposited onto the first boron-doped silicon germanium layer, e.g., the second boron-doped silicon germanium layer 220 (shown in FIG. 6), as shown with box 306. A boron-doped silicon layer is thereafter deposited onto the second boron-doped silicon germanium layer, e.g., the boron-doped silicon layer 222 (shown in FIG. 7), as shown with box 308. In certain examples the semiconductor structure may be formed without removing the semiconductor structure from the chamber arrangement and/or without using a cyclic deposition and etch technique, as shown with bracket 310. In accordance with certain examples, a semiconductor device like FinFET or gate-all-around device may be fabricated using the semiconductor structure, as shown with boxes 312-316. It is contemplated that an optional transition layer may be deposited onto the substrate prior to deposition of the first boron-doped silicon germanium layer, e.g., the optional transition layer 224 (shown in FIG. 5), as shown with box 317. In such examples the first boron-doped silicon germanium layer may be deposited onto (e.g., directly onto) the optional transition layer, as shown with box 318.

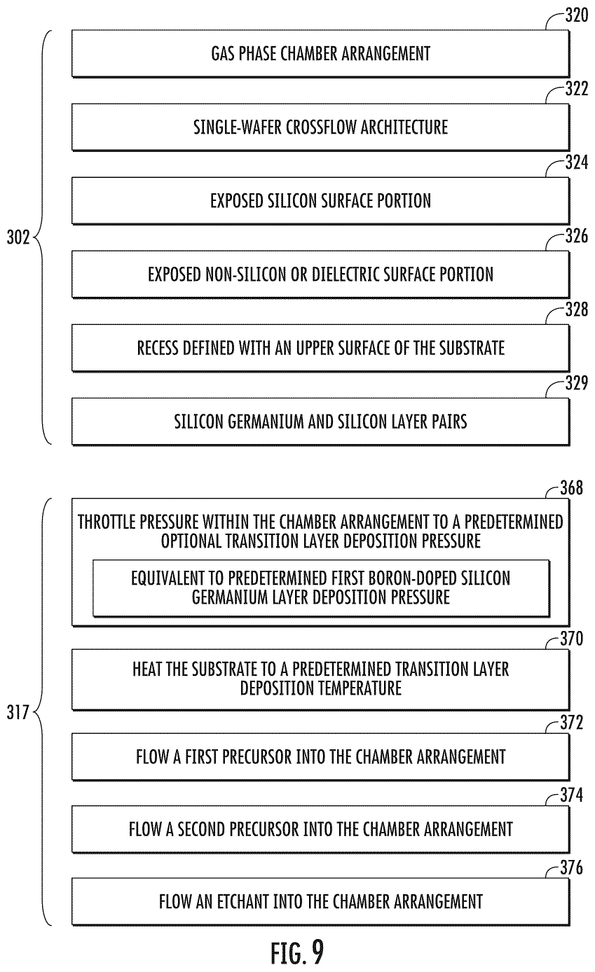

As shown in FIG. 9, seating 302 the substrate in the chamber arrangement may include seating the substrate in a gas phase chamber arrangement, as shown with box 320. Seating 302 the substrate in the chamber arrangement may include seating the substrate in a chamber arrangement having a single-wafer cross-flow architecture, e.g., the single-wafer cross-flow architecture 154 (shown in FIG. 3), as shown with box 322. Seating 302 the substrate in the chamber arrangement may include seating a substrate having an exposed silicon surface portion within the chamber arrangement, e.g., the exposed silicon surface portion 204 (shown in FIG. 4), as shown with box 324. Seating 302 the substrate in the chamber arrangement may include seating a substrate having an exposed non-silicon or dielectric surface portion in the chamber arrangement, e.g., the exposed non-silicon or dielectric surface portion 206 (shown in FIG. 4), as shown with box 326. Seating 302 the substrate in the chamber arrangement may include seating a substrate having both an exposed silicon surface portion and an exposed non-silicon or dielectric surface portion in the chamber arrangement, as shown with box 324 and box 326. It is contemplated that either (or both) the exposed silicon surface portion and the exposed non-silicon or dielectric surface portion may be defined within a recess in an upper surface of the substrate, e.g., the recess 210 (shown in FIG. 4), as shown with box 328. In such examples the recess may be bounded by layer pairs including alternating silicon germanium layers and silicon layers, which may be epitaxial with a crystalline structure of the substrate, as also shown with box 329.

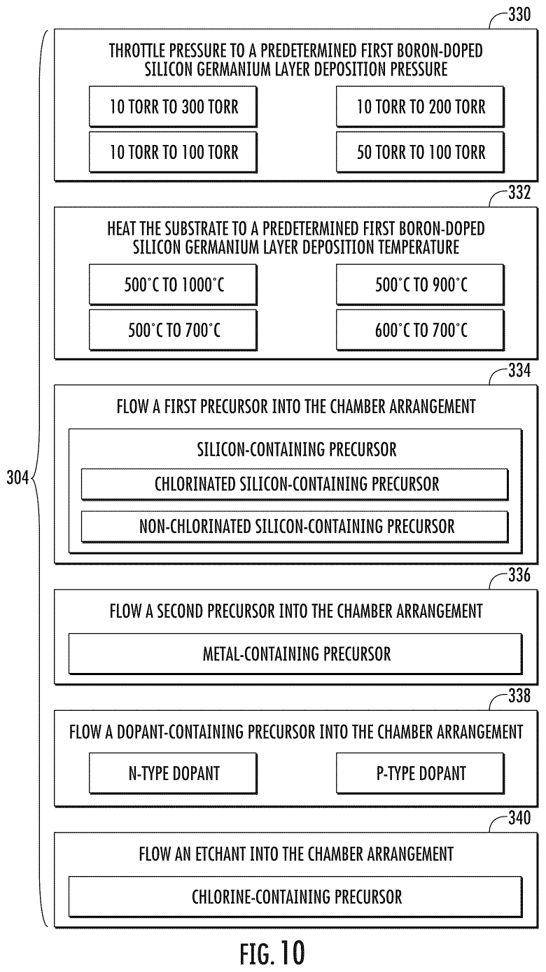

As shown in FIG. 10, depositing 304 the first boron-doped silicon germanium layer may include throttling pressure within an interior of the chamber arrangement to a predetermined first boron-doped layer deposition pressure, as shown with box 330. The predetermined first boron-doped silicon germanium layer deposition pressure may be between about 10 Torr and about 300 Torr, or between about 10 Torr and about 200 Torr, or between about 10 Torr and about 100 Torr, or even between about 50 Torr and about 100 Torr, as also shown with box 330. Depositing 304 the first boron-doped silicon germanium layer may include heating the substrate a predetermined first boron-doped silicon germanium layer deposition temperature during deposition of the first boron-doped silicon germanium layer, as shown with box 332. The predetermined first boron-doped silicon germanium layer deposition temperature may be between about 500 degrees Celsius and about 1000 degrees Celsius, or between about 500 degrees Celsius and about 900 degrees Celsius, or between about 500 degrees Celsius and about 700 degrees Celsius, or even between about 600 degrees Celsius and about 700 degrees Celsius, as also shown with box 332.

Depositing 304 the first boron-doped silicon germanium layer may include flowing a first precursor into the chamber arrangement, e.g., the first precursor 140 (shown in FIG. 2), as shown with box 334. In certain examples first precursor may include a silicon-containing precursor, as also shown with box 334. In accordance with certain examples, the first precursor may include a chlorinated silicon-containing precursor such as dichlorosilane (SiH₂Cl₂), trichlorosilane (SiHCl₃), and/or silicon tetrachloride (SiCl₄), as further shown with box 334. It is contemplated that the first precursor may (alternatively or additionally) include a non-chlorinated silicon-containing precursor such as silane (SiH₄), disilane (Si₂H₆), and/or trisilane (Si₃H₈), as additionally shown with box 334. Depositing 304 the first boron-doped silicon germanium layer may include flowing a second precursor into the chamber arrangement, e.g., the second precursor 142 (shown in FIG. 2), as shown with box 336. In certain examples the second precursor may include a metal-containing precursor, such as germanium (Ge), aluminum (Al), and/or gallium (Ga), as also shown with box 336. In this respect it is contemplated that the second precursor may include a chlorinated metal-containing precursor, such as germanium tetrachloride (GeCl₄), or a non-chlorinated metal-containing precursor like germane (GeH₄) or digermane (Ge₂H₆), as further shown with box 336.

Depositing 304 the first boron-doped silicon germanium layer may include flowing a dopant-containing precursor into the chamber arrangement, e.g., the dopant-containing precursor 144 (shown in FIG. 2), as shown with box 338. In this respect it is contemplated that the dopant-containing precursor may include a p-type dopant, such as boron (B) and/or phosphorus (P), such as may be flowed into the chamber arrangement as a dopant-containing precursor such as diborane (B₂H₆) and/or phosphine (PH₃), as also shown with box 338. In further respect, it is also contemplated that the dopant-containing precursor may include an n-type dopant like arsenic (As), which may be included flowed into the chamber arrangement using arsine (AsH₃), as further shown with box 338. Depositing 304 the first boron-doped silicon germanium layer may include flowing an etchant into the interior of the chamber arrangement, e.g., the etchant 146 (shown in FIG. 2), as shown with box 340. In certain examples the etchant may include chlorine (Cl) and in this respect may include chlorine (Cl₂) gas and/or hydrochloric acid (HCl). It is contemplated that the dopant-containing precursor and/or the etchant may be co-flowed into the chamber arrangement with one or more of the first precursor and the second precursor, for example to deposit the first boron-doped silicon germanium layer while limiting (or preventing) formation of boron-doped silicon germanium material onto the exposed non-silicon or dielectric surface portion of the substrate, as also shown with box 340.

It is contemplated that depositing 304 the first boron-doped silicon germanium layer may be isobaric, as further shown with box 330. In this respect pressure within the interior of the chamber arrangement may remain at the predetermined first boron-doped silicon germanium deposition pressure for substantially an entirety of first boron-doped silicon germanium deposition interval. It is also contemplated that the first boron-doped silicon germanium layer may be isothermal and in this respect the temperature of the substrate may remain at the predetermined first boron-doped silicon germanium layer deposition temperature for the entirety of the first boron-doped silicon germanium layer deposition interval, as further shown with box 332. It is further contemplated that temperature of the substrate may be controlled according to a non-contact temperature control technique or a contact temperature control technique, for example using one or more of the upper pyrometer 166 (shown in FIG. 3) and/or the lower pyrometer 198 (shown in FIG. 3) as well as the thermocouple 196 (shown in FIG. 3), as additionally shown with box 330.

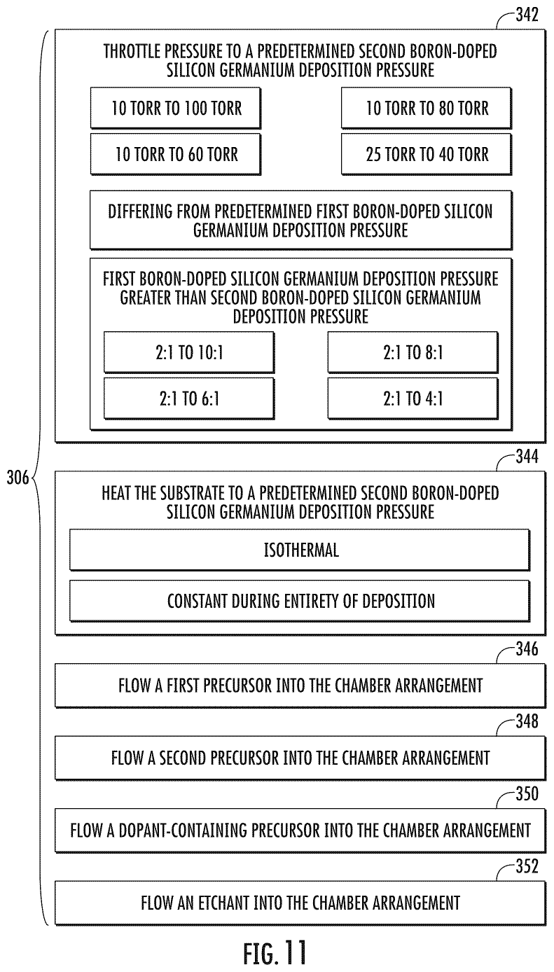

As shown in FIG. 11, depositing 306 the second boron-doped silicon germanium layer may include throttling pressure within an interior of the chamber arrangement to a predetermined second boron-doped layer deposition pressure, as shown with box 342. It is contemplated that the predetermined second boron-doped silicon germanium layer deposition pressure may differ from the predetermined first boron-doped silicon germanium layer deposition pressure, as also shown with box 342. In certain examples the predetermined first boron-doped silicon germanium deposition pressure may be greater than the predetermined second boron-doped silicon germanium layer deposition pressure, as further shown with box 342. In this respect it is contemplated that the predetermined second boron-doped silicon germanium layer deposition pressure may be between about 10 Torr and about 100 Torr, or between about 10 Torr and about 80 Torr, or between about 10 Torr and about 60 Torr, or even between about 25 Torr and about 40 Torr, as additionally shown with box 342. In further respect, it is also contemplated that a ratio of the predetermined first boron-doped silicon germanium deposition pressure to the second boron-doped silicon germanium deposition pressure may be between about 2:1 and about 10:1, or between about 2:1 and about 8:1, or between about 2:1 and about 6:1, or even between about 2:1 and 4:1, as also shown with box 342.

Depositing 306 the second boron-doped silicon germanium layer may include heating the substrate to a predetermined second boron-doped silicon germanium layer deposition temperature during deposition of the second boron-doped silicon germanium layer, as shown with box 344. In certain examples deposition of the second boron-doped silicon germanium layer may be isothermal with deposition of the first boron-doped silicon germanium layer, the predetermined second boron-doped silicon germanium layer deposition temperature being substantially equivalent to the predetermined first boron-doped silicon germanium layer deposition temperature in this respect, as also shown with box 344. In accordance with certain examples, temperature of the substrate may be maintained at the predetermined second boron-doped silicon germanium layer deposition temperature throughout an entirety of a deposition interval during which second boron-doped silicon germanium layer is deposited onto the first boron-doped silicon germanium layer, as shown with box 344.

Depositing 306 the second boron-doped silicon germanium layer may include flowing the first precursor and the second precursor into the chamber arrangement, as shown with box 346 and box 348. In this respect it is contemplated that a common first precursor and a common second precursor may flow in the chamber arrangement continuously and without interruption during deposition of both the first boron-doped silicon germanium layer and the second boron-doped silicon germanium layer, as shown with box 346 and box 348. Depositing 306 the second boron-doped silicon germanium layer may include flowing a dopant-containing precursor and an etchant into the chamber arrangement, as shown with box 350 and box 352. It is contemplated that a common dopant-containing precursor and a common etchant may be flowed into the chamber arrangement during deposition of both the first boron-doped silicon germanium layer and the second boron-doped silicon germanium layer, as also shown with box 350 and box 352. It is also contemplated that the common dopant-containing precursor and the common etchant may be flowed continuously and without interruption during deposition of both the first boron-doped silicon germanium layer and the second boron-doped silicon germanium layer, as further shown with box 350 and box 352. It is further contemplated that a mass flow rate of one or more of the precursor employed to deposit the second boron-doped silicon germanium layer may be throttled to terminate deposition of the first boron-doped silicon germanium layer and initiate deposition of the second boron-doped silicon germanium layer, for example by one or more of (a) decreasing mass flow rate of the first precursor, (b) increasing mass flow rate of the second precursor, (c) increasing mass flow rate of the dopant-containing precursor, and (d) increasing mass flow rate of the etchant, as additionally shown with boxes 346-352.

It is contemplated that the etchant may be co-flowed into the chamber arrangement with one or more of the first precursor and the second precursor as well as the dopant-containing precursor, for example to deposit the first boron-doped silicon germanium layer while limiting (or preventing) formation of boron-doped silicon germanium material onto the exposed non-silicon or dielectric surface portion of the substrate, as further shown with box 352. It is also contemplated that depositing 306 the second boron-doped silicon germanium layer may be isobaric subsequent to the aforementioned throttling of pressure within the chamber arrangement, as also shown with box 342, and that depositing 306 the second boron-doped silicon germanium layer may be isothermal for the entirety of a second boron-doped silicon germanium layer deposition interval, as shown with box 344. In certain examples temperature of the substrate may be controlled according to a non-contact temperature control technique or a contact temperature control technique. In this respect one or more of the upper pyrometer 166 (shown in FIG. 3), the lower pyrometer 198 (shown in FIG. 3), and the thermocouple 196 (shown in FIG. 3) may be employed to control temperature of the substrate during deposition of the second boron-doped silicon germanium layer, as additionally shown with box 344.

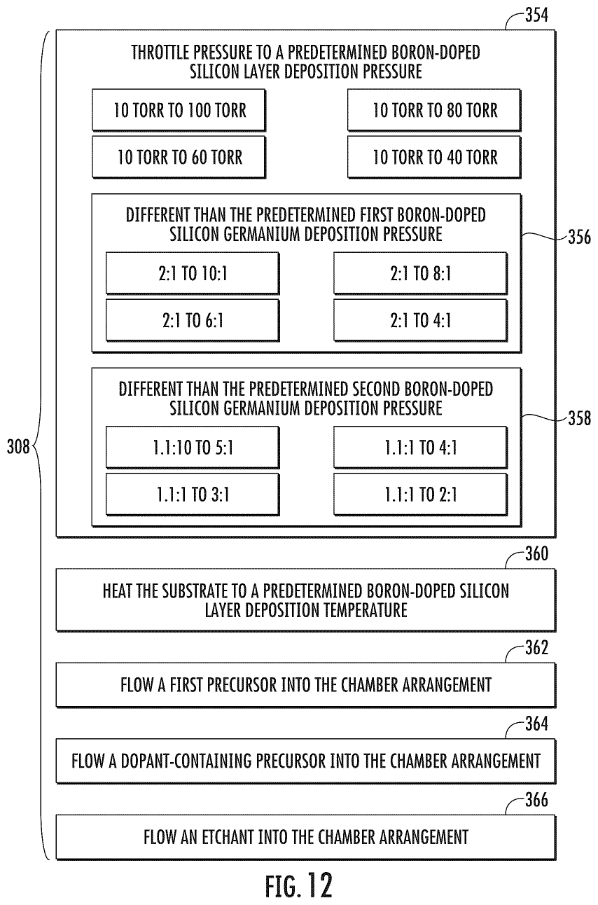

As shown in FIG. 12, depositing 308 the boron-doped silicon layer may include throttling pressure within the interior of the chamber arrangement to a predetermined boron-doped silicon layer deposition pressure, as shown with box 354. In this respect it is contemplated that the predetermined boron-doped silicon layer deposition pressure may be between about 10 Torr and about 100 Torr, or between about 10 Torr and about 80 Torr, or between about 10 Torr and about 60 Torr, or even between about 10 Torr and about 40 Torr, as also shown with box 354. In certain examples the predetermined boron-doped silicon layer deposition pressure may differ from either (or both) the predetermined first boron-doped silicon germanium layer deposition pressure and the predetermined second boron-doped silicon germanium layer deposition pressure, as shown with box 356 and box 358. For example, the predetermined boron-doped silicon layer deposition pressure may be greater than the predetermined second boron-doped silicon germanium layer deposition pressure, as also shown with box 356. Alternatively, the predetermined boron-doped silicon layer deposition pressure may be less than the predetermined first boron-doped silicon germanium layer deposition pressure, as also shown with box 358. It is also contemplated that, in accordance with certain examples, that the predetermined boron-doped silicon layer deposition pressure may be both greater than the predetermined second boron-doped silicon germanium layer deposition pressure and less than the predetermined first boron-doped silicon germanium layer deposition pressure and remain within the scope of the present disclosure, as also shown with both box 356 and box 358.

In certain examples a ratio of the predetermined first boron-doped silicon germanium deposition pressure to the predetermined boron-doped silicon layer may be between about 2:1 and about 10:1, or between about 2:1 and about 8:1, or between about 2:1 and about 6:1, or even between about 2:1 and about 4:1, as also shown with box 356. In accordance with certain examples, a ratio of the predetermined boron-doped silicon layer deposition pressure to the predetermined second boron-doped silicon germanium deposition pressure may be between about 1.1:10 and about 5:1, or between about 1.1:1 and about 4:1, or between about 1.1:1 and about 3:1, or even between about 1.1:1 and about 2:1, as further shown with box 358. In accordance with certain examples, deposition of the boron-doped silicon layer may be isobaric subsequent to establishing the predetermined boron-doped silicon layer deposition pressure within the chamber arrangement, as shown with box 354. Advantageously, pressure ratios within these ranges enable forming the semiconductor structure continuously in a deposition regime that employs different pressures for deposition of successive layers. To further advantage, temperature of the substrate may be maintained at a common deposition temperature during the forming of the semiconductor structure while maintaining selectivity to silicon surfaces relative to exposed non-silicon or dielectric surfaces. As will be appreciated by those of skill in the art in view of the present disclosure, this may limit time required to deposit the semiconductor structure (and increase throughput of the semiconductor processing system employed to form the semiconductor structure) by avoiding the need to stabilize temperature following a temperature setpoint change and/or interrupt deposition for an intervening etch cycle which could otherwise be required to form the semiconductor structure.

Depositing 308 of the boron-doped silicon layer may include heating the substrate to a predetermined boron-doped silicon layer deposition temperature during deposition of the boron-doped silicon layer onto the second boron-doped silicon germanium layer, as shown with box 360. In this respect it is contemplated that deposition of the boron-doped silicon layer may be isothermal with the deposition of the second boron-doped silicon germanium layer, as also shown with box 360. In certain examples deposition of the boron-doped silicon layer may be isobaric with deposition of the second boron-doped silicon germanium layer, the predetermined boron-doped silicon layer deposition pressure being substantially equivalent to the predetermined second boron-doped silicon germanium layer deposition pressure, as further shown with box 360. In accordance with certain examples, temperature of the substrate may be maintained at the predetermined boron-doped silicon layer deposition temperature may be substantially constant throughout an entirety of a deposition interval during which boron-doped silicon layer is deposited onto the first boron-doped silicon germanium layer, as additionally shown with box 360. It is contemplated that temperature of the substrate may be controlled according to a non-contact temperature control technique or a contact temperature control technique, for example using one or more of the upper pyrometer 166 (shown in FIG. 3) and/or the lower pyrometer 198 (shown in FIG. 3) as well as the thermocouple 196 (shown in FIG. 3), as also shown with box 360.

Depositing 308 the boron-doped silicon layer may include flowing a first precursor into the chamber arrangement, as shown with box 362. In certain examples a common first precursor may be employed for deposition of both the boron-doped silicon material layer and the second boron-doped silicon germanium layer, as also shown with box 362. In accordance with certain examples, the first precursor may be flowed continuously and without interruption during deposition of both the boron-doped silicon layer and the boron-doped silicon germanium layer, as further shown with box 362.

Depositing 308 the boron-doped silicon layer may include flowing additional dopant-containing precursor into the chamber arrangement, as shown with box 364. In certain examples a common dopant-containing precursor may be employed for deposition of both the boron-doped silicon material layer and the second boron-doped silicon germanium layer, as also shown with box 364. In accordance with certain examples, the dopant-containing precursor may be flowed continuously and without interruption during deposition of both the boron-doped silicon layer and the second boron-doped silicon germanium layer, as further shown with box 364. In such examples flow of the dopant-containing precursor may cease between deposition of the second boron-doped silicon germanium layer and the boron-doped silicon layer, for example to limit dopant concentration variation at an interface of the boron-doped silicon layer and the second boron-doped silicon germanium layer, as shown with box 364. It is contemplated that the dopant-containing precursor may be co-flowed into the chamber arrangement during deposition of the boron-doped silicon layer, as also shown with box 364.

Depositing 308 the boron-doped silicon layer may include flowing additional etchant into the chamber arrangement, as shown with box 366. In such examples a common etchant may be flowed into the chamber arrangement during deposition of both the boron-doped silicon material layer and the second boron-doped silicon germanium layer, as also shown with box 366. It is contemplated that the etchant may be co-flowed with either (or both) the first precursor and/or the dopant-containing layer during deposition of the boron-doped silicon layer, for example to provide selectivity during deposition of the boron-doped silicon layer by limiting (or eliminating) deposition of boron-doped silicon material onto the exposed non-silicon or dielectric surface portion of the substrate while depositing the boron-doped silicon layer onto the second boron-doped silicon germanium layer, as shown with box 366. It is further contemplated mass flow rate of one or more of the first precursor, the dopant-containing precursor, and/or the etchant employed to deposit the boron-doped silicon layer may be throttled to terminate deposition of the second boron-doped silicon germanium layer and initiate deposition of the boron-doped silicon layer. In this respect it is contemplated that (a) mass flow rate of the first precursor flowed into the chamber arrangement may be increased, (b) mass flow rate of the dopant-containing precursor flowed into the chamber arrangement may be increased, and/or (c) mass flow rate of the etchant flowed into the chamber arrangement may be decreased, as shown with box 366.

With continuing reference to FIG. 9, depositing 317 the optional transition layer may include throttling pressure within the interior of the chamber arrangement to a transition layer deposition pressure, for example to a transition layer deposition pressure that may be substantially equivalent to the first boron-doped silicon germanium layer deposition pressure, as shown with box 368. Depositing 317 the optional transition layer may include heating the substrate to a predetermined transition layer deposition temperature, for example to a predetermined transition layer deposition temperature that is substantially equivalent to the predetermined first boron-doped silicon germanium layer deposition temperature, as shown with box 370. In accordance with certain examples, temperature of the substrate may be controlled using a non-contact temperature sensor, such as the upper pyrometer and/or the lower pyrometer, as well as a contact temperature sensor like the thermocouple, as also shown with box 368.

Depositing 317 the optional transition layer may include flowing a first precursor and a second precursor into the chamber arrangement, as shown with box 372 and box 374. Depositing 317 the optional transition layer may include flowing (e.g., co-flowing) an etchant into the interior of the chamber arrangement, for example such that substantially no silicon germanium material forms onto the exposed non-silicon or dielectric surface portion of the substrate, as shown with box 376. Depositing 317 the optional transition layer may include selectively depositing the optional transition layer onto the exposed silicon surface portion of the substrate, for example that the optional transition layer is epitaxial with the exposed silicon surface portion, as also shown with boxes 372-374. It is contemplated that depositing 317 the optional transition layer may include depositing the optional transition layer such that the optional transition layer consists of, or consists essentially of, silicon germanium and, in this respect the optional transition layer may be undoped, as further shown with boxes 372-374.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A semiconductor processing system, comprising:
a chamber arrangement; and
a processor operatively connected to the chamber arrangement and responsive to instructions recorded on a non-transitory machine-readable medium to:
seat a substrate in the chamber arrangement;
deposit a first boron-doped silicon germanium layer on the substrate;
deposit a second boron-doped silicon germanium layer onto the first boron-doped silicon germanium layer; and
deposit a boron-doped silicon layer onto the second boron-doped silicon germanium layer,
wherein the first boron-doped silicon germanium layer is deposited at a first boron-doped silicon germanium layer deposition pressure,
wherein the second boron-doped silicon germanium layer is deposited at a second boron-doped silicon germanium layer deposition pressure, and
wherein the first boron-doped silicon germanium layer deposition pressure is greater than the second boron-doped silicon germanium layer deposition pressure.

2. The system of claim 1, wherein the first boron-doped silicon germanium layer deposition pressure is between about 10 Torr and about 300 Torr; and wherein the second boron-doped silicon germanium layer deposition pressure is between about 10 Torr and about 100 Torr.

3. The system of claim 1, wherein a ratio of the first boron-doped silicon germanium layer deposition pressure to the second boron-doped silicon germanium layer deposition pressure is between about 2:1 and about 10:1.

4. The system of claim 1, wherein the instructions further cause the processor to deposit the boron-doped silicon layer at a boron-doped silicon layer deposition pressure, and wherein the boron-doped silicon layer deposition pressure is greater than the second boron-doped silicon germanium layer deposition pressure.

5. The system of claim 4, wherein the boron-doped silicon layer deposition pressure is less than the first boron-doped silicon germanium layer deposition pressure; wherein the boron-doped silicon layer deposition pressure is between about 10 Torr and about 100 Torr; and wherein a ratio of the boron-doped silicon layer deposition pressure to the second boron-doped silicon germanium layer deposition pressure is between about 1.1:1 and about 5:1.

6. The system of claim 1, wherein the instructions further cause the processor to maintain the substrate at a temperature between about 500 degrees Celsius and about 1000 degrees Celsius, continuously during deposition of each of the first boron-doped silicon germanium layer, the second boron-doped silicon germanium layer, and the boron-doped silicon layer.

7. The system of claim 1, further comprising a precursor source coupled to the chamber arrangement and operatively associated with the processor; and wherein the instructions further cause the processor to continuously flow a silicon-containing precursor, a germanium-containing precursor, and an etchant into the chamber arrangement from the precursor source during deposition of the first boron-doped silicon germanium layer, the second boron-doped silicon germanium layer, and the boron-doped silicon layer.

8. The system of claim 1, further comprising a precursor source coupled to the chamber arrangement and operatively associated with the processor, and wherein the instructions further cause the processor to:
continuously flow a boron-containing precursor into the chamber arrangement from the precursor source during deposition of the first boron-doped silicon germanium layer, the second boron-doped silicon germanium layer;
cease flow of the boron-containing precursor from the precursor source and into the chamber arrangement; and
thereafter resume flow of the boron-containing precursor from the precursor source and into the chamber arrangement.

9. A method of forming a semiconductor structure, comprising:
seating a substrate in a chamber arrangement;
depositing a first boron-doped silicon germanium layer on the substrate;
depositing a second boron-doped silicon germanium layer onto the first boron-doped silicon germanium layer; and
depositing a boron-doped silicon layer onto the second boron-doped silicon germanium layer,
wherein the first boron-doped silicon germanium layer is deposited at a first boron-doped silicon germanium layer deposition pressure,
wherein the second boron-doped silicon germanium layer is deposited at a second boron-doped silicon germanium layer deposition pressure, and
wherein the first boron-doped silicon germanium layer deposition pressure is greater than the second boron-doped silicon germanium layer deposition pressure to limit time required to form the semiconductor structure.

10. The method of claim 9, wherein the first boron-doped silicon germanium layer deposition pressure is between about 10 Torr and about 300 Torr; and wherein a ratio of the first boron-doped silicon germanium layer deposition pressure to the second boron-doped silicon germanium layer deposition pressure is between about 1.1:1 and about 5:1.

11. The method of claim 9, wherein the boron-doped silicon layer is deposited at a boron-doped silicon layer deposition pressure, and wherein the boron-doped silicon layer deposition pressure is greater than the second boron-doped silicon germanium layer deposition pressure; and wherein the boron-doped silicon layer deposition pressure is less than the first boron-doped silicon germanium layer deposition pressure.

12. The method of claim 11, wherein the boron-doped silicon layer deposition pressure is between about 10 Torr and about 100 Torr.

13. The method of claim 11, wherein a ratio of the first boron-doped silicon germanium layer deposition pressure to the second boron-doped silicon germanium layer deposition pressure is between about 2:1 and about 10:1.

14. The method of claim 9, further comprising continuously heating the substrate to a temperature between about 500 degrees Celsius and about 1000 degrees Celsius during deposition of the first boron-doped silicon germanium layer, the second boron-doped silicon germanium layer, and the boron-doped silicon layer.

15. The method of claim 9, further comprising continuously flowing a germanium-containing precursor into the chamber arrangement during deposition of the first boron-doped silicon germanium layer, the second boron-doped silicon germanium layer, and the boron-doped silicon layer.

16. The method of claim 9, further comprising:
continuously flowing a silicon-containing precursor into the chamber arrangement during deposition of the first boron-doped silicon germanium layer, the second boron-doped silicon germanium layer, and the boron-doped silicon layer; and
continuously flowing an etchant into the chamber arrangement during deposition of the first boron-doped silicon germanium layer, the second boron-doped silicon germanium layer, and the boron-doped silicon layer.

17. The method of claim 9, further comprising:
continuously flowing a boron-containing precursor into the chamber arrangement during deposition of the first boron-doped silicon germanium layer, the second boron-doped silicon germanium layer;
ceasing flow of the boron-containing precursor into the chamber arrangement to cease deposition of the second boron-doped silicon germanium layer; and
thereafter resuming flow of the boron-containing precursor into the chamber arrangement to begin deposition of the boron-doped silicon layer.

18. The method of claim 9, wherein seating the substrate includes seating a substrate having an exposed silicon surface portion and an exposed non-silicon or dielectric surface portion in the chamber arrangement; wherein the first boron-doped silicon germanium layer, the second boron-doped silicon germanium layer, and the boron-doped silicon layer are epitaxial with the exposed silicon surface; and wherein substantially no amorphous or polycrystalline boron-doped silicon germanium material and boron-doped silicon material are deposited onto the exposed non-silicon or dielectric surface portion during the forming of the semiconductor structure.

19. A semiconductor structure formed using the method of claim 9, wherein a germanium concentration of the second boron-doped silicon germanium layer is between about 20 atomic percent and about 45 atomic percent.

20. A computer program product, comprising:
a non-transitory machine-readable medium having instructions recorded in a plurality of program modules that, when read by a processor operably connected to a chamber arrangement of a semiconductor processing system cause the processor to:
seat a substrate in the chamber arrangement;
deposit a first boron-doped silicon germanium layer on the substrate;
deposit a second boron-doped silicon germanium layer onto the first boron-doped silicon germanium layer; and
deposit a boron-doped silicon layer onto the second boron-doped silicon germanium layer, wherein the first boron-doped silicon germanium layer is deposited at a first boron-doped silicon germanium layer deposition pressure, wherein the second boron-doped silicon germanium layer is deposited at a second boron-doped silicon germanium layer deposition pressure, and wherein the first boron-doped silicon germanium layer deposition pressure is greater than the second boron-doped silicon germanium layer deposition pressure.
